(19) United States
(12) Patent Application Publication
(10) Pub. No.: US 2010/0214247 A1
(43) Pub. Date: Aug. 26, 2010

(54) Capacitive Touch Panel

(75) Inventors: Tung-Yang Tang, Tainan City (TW); Hung-Jung Chang, Tainan City (TW)

Correspondence Address: THE MUELLER LAW OFFICE, P.C., 12951 Harwick Lane, San Diego, CA, 92130, US

(73) Assignee: ACROSENSE TECHNOLOGY CO., LTD., Tainan City (TW)

(21) Appl. No.: 12/708,308

(22) Filed: Feb. 18, 2010

Related U.S. Application Data
(63) Continuation-in-part of application No. 12/547,438, filed on Aug. 25, 2009.

(30) Foreign Application Priority Data
Feb. 20, 2009 (TW) 098202527

(51) Int. Cl. G06F 3/041; H03K 17/975

(52) U.S. Cl. 345/173; 200/600

(57) ABSTRACT

A capacitive touch panel includes a substrate having a pattern-forming surface, a color pixel layer formed on the substrate, and a patterned conductive layer formed on the pattern-forming surface of the substrate. The patterned conductive layer includes a plurality of first electrode units, a plurality of second electrode units, a plurality of spaced apart first conductive lines, and a plurality of spaced apart second conductive lines. The first electrode units are capacitively coupled to the second electrode units so as to form a plurality of two dimensionally arranged capacitive sensing units. Each of the first electrode units includes a plurality of first electrodes. Each of the first conductive lines is connected to and extends along the pattern-forming surface from at least one of the first electrodes of a respective one of the first electrode units into a bonding area of the pattern-forming surface. The second conductive lines extend respectively from the second electrode units into the bonding area, and do not cross the first conductive lines.

### CROSS-REFERENCE TO RELATED APPLICATION

This application is a continuation-in-part of U.S. patent application Ser. No. 12/547,438, filed on Aug. 25, 2009, which claims the benefit of Taiwanese Application No. 098202527, filed on Feb. 20, 2009. The contents of U.S. patent application Ser. No. 12/547,438 and Taiwanese Application No. 098202527 are incorporated herein by reference.

### BACKGROUND OF THE INVENTION

1. Field of the Invention

This invention relates to a capacitive touch panel, more particularly to a capacitive touch panel including a patterned conductive layer having two dimensionally arranged first and second electrodes and first and second conductive lines which are formed directly on the same surface of a substrate.

2. Description of the Related Art

Taiwanese Application No. 096115152 discloses a conventional capacitive touch panel that includes a substrate, alternately disposed first and second electrodes formed on the substrate, first conductive lines, second conductive lines, and insulator pads. The first electrodes are arranged into parallel columns. The second electrodes are arranged into parallel rows. Each of the first conductive lines interconnects two adjacent ones of the first electrodes of a respective one of the columns of the first electrodes. Each of the insulator pads covers a portion of a respective one of the first conductive lines. Each of the second conductive lines interconnects two adjacent ones of the second electrodes of a respective one of the rows of the second electrodes, and crosses and is separated from the portion of a respective one of the first conductive lines by a respective one of the insulator pads. U.S. Patent Publication No. 2008/0246496 discloses another conventional capacitive touch panel that includes a substrate, first and second electrodes formed on the substrate, first conductive lines, and second conductive lines. The first and second electrodes extend in a first direction and are interleaved in a second direction. The second electrodes are divided into three groups. Each of the first conductive lines is connected to a respective one of the first electrodes. Each of the second conductive lines is connected to one of the groups of the second electrodes. The second conductive lines have via portions by which the second conductive lines cross and bypass the first conductive lines while extending from the respective second electrodes to a bonding area for connecting with an external connector.

Therefore, the aforementioned two conventional capacitive touch panels need at least two patterned layers for layout of the first and second electrodes or one substrate with insulating layer(s) and via contacts for layout of the first and second conductive lines. Moreover, the aforementioned two conventional capacitive touch panels are disadvantageous in that they have complicated layer structures and require complicated manufacturing processes, which results in high manufacturing costs, and that they are difficult to be integrated with a color filter or an array of color pixels, each including at least three sub-pixel color elements, such as Red, Green and Blue color elements, to form an in-cell capacitive touch panel.

### SUMMARY OF THE INVENTION

Therefore, the object of the present invention is to provide a capacitive touch panel that has a simple single layer structure on a surface of a substrate and is easy to be integrated with a color filter to form an in-cell capacitive touch panel.

According to one aspect of this invention, there is provided a capacitive touch panel that comprises a substrate, a color pixel layer, and a patterned conductive layer. The substrate has a pattern-forming surface that is divided into an electrode-forming region and a peripheral region surrounding the electrode-forming region and having a bonding area. The color pixel layer is disposed on the substrate and has an array of color pixels, each of which includes at least three sub-pixel color elements that are different in color. The patterned conductive layer is formed on the pattern-forming surface and includes a plurality of first electrode units formed on the electrode-forming region and aligned in a first direction, a plurality of second electrode units formed on the electrode-forming region and aligned in a second direction transverse to the first direction, a plurality of spaced apart first conductive lines, and a plurality of spaced apart second conductive lines. The first electrode units are capacitively coupled to the second electrode units so as to form a plurality of two dimensionally arranged capacitive sensing units in the electrode-forming region. Each of the first electrode units includes a plurality of first electrodes that are aligned in the second direction. Each of the first conductive lines is connected to and extends from at least one of the first electrodes of a respective one of the first electrode units into the peripheral region. The first conductive lines converge at the bonding area for electrically bonding to an external connector. The second conductive lines extend respectively from the second electrode units into the peripheral region, converge at the bonding area for electrically bonding to the external connector, and do not cross the first conductive lines.

According to another aspect of this invention, there is provided a capacitive touch panel that comprises a substrate, a color pixel layer, a patterned conductive layer, and a connector. The substrate has a pattern-forming surface that is divided into an electrode-forming region and a peripheral region surrounding the electrode-forming region and having a bonding area. The color pixel layer is disposed on the substrate and has an array of color pixels, each of which includes at least three sub-pixel color elements that are different in color. The patterned conductive layer is formed on the pattern-forming surface and includes a plurality of first electrode units formed on the electrode-forming region, a plurality of second electrode units formed on the electrode-forming region, a plurality of spaced apart first conductive lines, and a plurality of spaced apart second conductive lines. The first electrode units are capacitively coupled to the second electrode units so as to form a plurality of two dimensionally arranged capacitive sensing units in the electrode-forming region. Each of the first electrode units includes a plurality of first electrodes. The connector is bonded to the bonding area of the peripheral region of the pattern-forming surface of the substrate for connecting electrically the first and second electrode units to the controller. The connector has a plurality of spaced apart first conductive fingers and a plurality of spaced apart second conductive fingers. Each of the first conductive lines is connected to and extends from at least one of the first electrodes of a respective one of the first electrode units into the peripheral region. The first conductive lines converge at the bonding area to connect electrically with the first conductive fingers, respectively. The second conductive lines extend respectively from the second electrode units into the peripheral region, do not cross the first conductive lines, and converge at the bonding area to connect electrically with the second conductive fingers, respectively.

According to yet another aspect of this invention, there is provided a capacitive touch panel that comprises a substrate, a color pixel layer, and a patterned conductive layer. The color pixel layer is formed on the substrate and has an array of color pixels, each of which includes at least three sub-pixel color elements that are different in color. The sub-pixel color elements of the pixels cooperatively define a network of grooves thereamong. The color pixel layer further has a black matrix filling the grooves. The patterned conductive layer includes a plurality of first electrode units formed on the black matrix and aligned in a first direction, and a plurality of second electrode units formed on the black matrix and aligned in a second direction transverse to the first direction. The first electrode units are capacitively coupled to the second electrode units so as to form a plurality of two dimensionally arranged capacitive sensing units on the black matrix.

According to still another aspect of this invention, there is provided a capacitive touch panel that comprises: a first substrate having a pattern-forming surface that is divided into an electrode-forming region and a peripheral region surrounding the electrode-forming region and having a bonding area; a patterned conductive layer formed on the pattern-forming surface and including a plurality of first electrode units formed on the electrode-forming region, a plurality of second electrode units formed on the electrode-forming region, a plurality of spaced apart first conductive lines, and a plurality of spaced apart second conductive lines, the first electrode units being capacitively coupled to the second electrode units so as to form a plurality of two dimensionally arranged capacitive sensing units in the electrode-forming region, each of the first electrode units including a plurality of first electrodes, each of the first conductive lines being connected to and extending along the pattern-forming surface from at least one of the first electrodes of a respective one of the first electrode units into the bonding area of the peripheral region, the second conductive lines extending along the pattern-forming surface from the second electrode units into the bonding area of the peripheral region, respectively, and not crossing the first conductive lines; and a second substrate spaced apart and overlapping the first substrate and having opposite first and second surfaces. The first surface is formed with a plurality of spaced apart first conductive fingers and a plurality of spaced apart second conductive fingers. The first and second fingers are adhesively bonded to the first and second conductive lines, respectively. The second surface is formed with a plurality of conductive linking lines. The second substrate is formed with a plurality of via units, each of which includes a plurality of vias extending through the first and second surfaces and connected electrically to a respective one of the linking and a respective one of the first conductive lines.

### BRIEF DESCRIPTION OF THE DRAWING

Other features and advantages of the present invention will become apparent in the following detailed description of the preferred embodiments of this invention, with reference to the accompanying drawings, in which:

FIG. 1 is a schematic view of the first preferred embodiment of a capacitive touch panel according to this invention;

FIG. 2 is a partly sectional view of the first preferred embodiment;

FIG. 3 is a schematic view illustrating the configuration of a capacitive sensing unit of the first preferred embodiment;

FIG. 4 is a schematic view of the second preferred embodiment of a capacitive touch panel according to this invention;

FIG. 5 is a schematic view illustrating a capacitive sensing unit of the second preferred embodiment;

FIG. 6 is a schematic view of the third preferred embodiment of a capacitive touch panel according to this invention;

FIG. 7 is a schematic view of the fourth preferred embodiment of a capacitive touch panel according to this invention;

FIG. 8 is a schematic view of the fifth preferred embodiment of a capacitive touch panel according to this invention;

FIG. 9 is a schematic view of the sixth preferred embodiment of a capacitive touch panel according to this invention;

FIG. 10 is a schematic view of the seventh preferred embodiment of a capacitive touch panel according to this invention;

FIG. 11 is a fragmentary schematic view of the eighth preferred embodiment of a capacitive touch panel according to this invention, with a color filter removed from the drawing for illustrating the structure of a conductive patterned layer;

FIG. 12 is an enlarged view of a lower portion of FIG. 11, with a black matrix of the color filter removed from the drawing;

FIG. 13 is a sectional view of the eighth preferred embodiment of a capacitive touch panel according to this invention;

FIG. 14 is a sectional view of the ninth preferred embodiment of a capacitive touch panel according to this invention;

FIG. 15 is a sectional view of the tenth preferred embodiment of a capacitive touch panel according to this invention;

FIG. 16 is a sectional view of the eleventh preferred embodiment of a capacitive touch panel according to this invention;

FIG. 17 is a sectional view of the twelfth preferred embodiment of a capacitive touch panel according to this invention; and

FIG. 18 is a fragmentary, exploded perspective view of the thirteenth preferred embodiment of a capacitive touch panel according to this invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

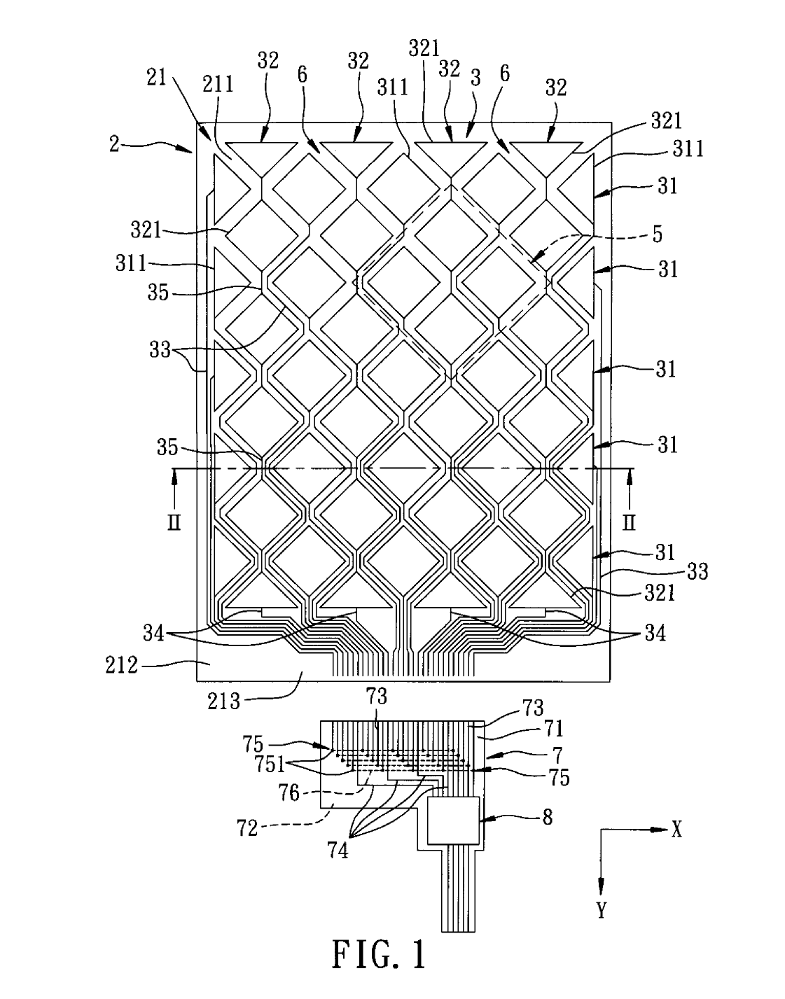

FIGS. 1 to 3 illustrate the first preferred embodiment of a capacitive touch panel according to this invention. The capacitive touch panel is connected to a controller 8, and includes a substrate 2, a patterned conductive layer 3, and a connector 7.

The substrate 2 has a pattern-forming surface 21 that is divided into an electrode-forming region 211 and a peripheral region 212. The peripheral region 212 surrounds the electrode-forming region 211, and has a bonding area 213 adjacent to a bottom side of the electrode-forming region 211.

The patterned conductive layer 3 is formed on the pattern-forming surface 21, and includes a plurality of first electrode units 31 formed on the electrode-forming region 211 and aligned in a first direction (Y), a plurality of second electrode units 32 formed on the electrode-forming region 211 and aligned in a second direction (X) transverse to the first direction (Y), a plurality of spaced apart first conductive lines 33, a plurality of spaced apart second conductive lines 34, and a plurality of conductive interconnecting lines 35. The entire patterned conductive layer 3 can be grown directly on the pattern-forming surface 21 or transferred from another substrate (not shown) to the pattern-forming surface 21.

Each of the first electrode units 31 includes a plurality of first electrodes 311 that are aligned in the second direction (X). Each of the second electrode units 32 includes a plurality of second electrodes 321 that are aligned in the first direction (Y). The second electrodes 321 of two adjacent ones of the second electrode units 32 cooperatively define a channel 6 therebetween. The channels 6 defined by the second electrodes 321 of the second electrode units 32 extend in the first direction (Y) from a top side (also referred to as one side herein) of the electrode-forming region 211 to the bottom side (also referred to as an opposite side herein) of the electrode-forming region 211. The first electrodes 311 of each of the first electrode units 31 are disposed respectively in the channels 6.

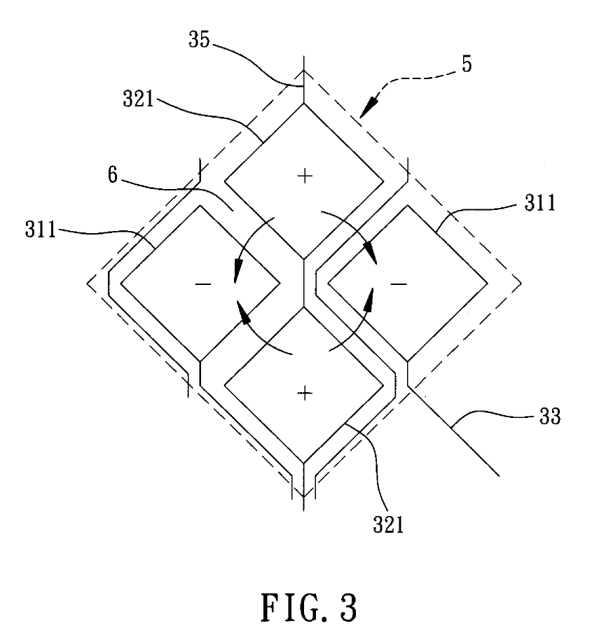

The first electrode units 31 are capacitively coupled to the second electrode units 32 so as to form a plurality of two dimensionally arranged capacitive sensing units 5 in the electrode-forming region 211. Each of the capacitive sensing units 5 includes two adjacent ones of the first electrodes 311 and two of the second electrodes 321 adjacent thereto. Electric fields generated by each of the capacitive sensing units 5 are represented by arrows in FIG. 3.

Each of the first conductive lines 33 is connected to and extends from a respective one of the first electrodes 311 of a respective one of the first electrode units 31 into the peripheral region 212. Some of the first conductive lines 33, each extending from the respective one of the first electrodes 311 that is disposed at the bottom side of the electrode-forming region 211 adjacent to the bonding area 213, are disposed outside of the electrode-forming region 211, while each of the remainder of the first conductive lines 33 extends from the respective one of the first electrodes 311 into and through the channel 6 in which the respective one of the first electrodes 311 is disposed. Also, the first conductive lines 33 converge at the bonding area 213 for electrically bonding to the connector 7.

The second conductive lines 34 extend respectively from the second electrode units 32 into the peripheral region 212. Particularly, each of the second conductive lines 34 is connected to a respective one of the second electrodes 321 of a respective one of the second electrode units 32 that is disposed at the bottom side of the electrode-forming region 211 adjacent to the bonding area 213. Also, the second conductive lines 34 converge at the bonding area 213 for electrically bonding to the connector 7, and do not cross the first conductive lines 33.

It is noted herein that an important optical quality of the capacitive touch panel that must be satisfied is that in which the first and second electrode units 31, 32 and the first and second conductive lines 33, 34 are substantially invisible. Hence, the first and second electrode units 31, 32 and the first and second conductive lines 33, 34 can be formed of ultra-thin films of Indium Tin Oxide (ITO) for achieving invisibility. However, since there is an inverse relationship between the layer thickness of the ITO layer and the electrical resistivity of the ITO layer (i.e., the less the layer thickness of the ITO layer, the greater the electrical resistivity of ITO layer), and since the first and second conductive lines 33, 34 are relatively long, an insulating layer(s) and vias for shortening the first and second conductive lines 33, 34 and metal used as material for portions of the first and second conductive lines 33, 34 in the conventional designs in order to reduce the electrical resistivity are required. For instance, the aforementioned conventional capacitive touch panel disclosed in U.S. Patent Publication No. 2008/0246496 has at least one insulating layer formed on the substrate and vies in order to connect portions of conductive lines (made from ITO) with the remaining portions of the conductive lines (made from metal) outside the active area (i.e., within the electrode forming region). As such, the first and second conductive lines of the aforementioned conventional capacitive touch panel are brought to cross each other. In the preferred embodiments of this invention, the ITO layer of the first and second conductive lines 33, 34 is thick enough to achieve low resistance to satisfy the RC requirements of ICs (integrated circuits) and to permit the first and second conductive lines 33, 34 to extend from the first and second electrodes 311, 321 to the bonding area 213 in a manner such that the first and second conductive lines 33, 34 do not cross each other. Alternatively, the first and second conductive lines 33, 34 can also be made using very thin metal lines, which are nearly invisible with a line width less than 30 micrometers. If ITO is used as the conductive line material or electrode material, the ITO layer thickness has to be greater than 70 nm for a 3″ capacitive touch panel and 200 nm for a 4″ or larger capacitive touch panel so as to satisfy the RC requirements for ICs. Since ITO has a large absorption in the blue light regime and since an increase in the thickness of the ITO layer results in an increase in the absorption in the blue regime, extra compensation or an anti-reflection layer(s) must be formed on the ITO layer to minimize the visibility of these ITO patterns.

Each of the interconnecting lines 35 interconnects two adjacent ones of the second electrodes 321 of a respective one of the second electrode units 32. Therefore, the second electrodes 321 of each of the second electrode units 32 have the same potential when activated.

The connector 7, which may be a flexible printed circuit board, is bonded to the bonding area 213 of the peripheral region 212 of the pattern-forming surface 21 of the substrate 2 for connecting electrically the first electrode units 31 and the second electrode units 32 to the controller 8. The connector 7 has a bonding surface 71, a connecting surface 72 opposite to the bonding surface 71, a plurality of spaced apart first conductive fingers 73 formed on the bonding surface 71, a plurality of spaced apart second conductive fingers 74 formed on the bonding surface 71, a plurality of via units 75 extending through the bonding surface 71 and the connecting surface 72, and a plurality of spaced apart conductive linking lines 76 formed on the connecting surface 72.

The first conductive fingers 73 are bonded respectively to the first conductive lines 33 so as to connect electrically therewith. The second conductive fingers 74 are bonded respectively to the second conductive lines 34 so as to connect electrically therewith.

Each of the via units 75 has a plurality of vias 751 connected electrically to a respective one of the linking lines 76. Each of the vias 751 of each of the via units 75 is connected electrically to a respective one of the first conductive fingers 73. Particularly, the vias 751 of each of the via units 75 are connected electrically to the first conductive fingers 73 that are bonded to the first conductive lines 33 extending from the first electrodes 311 of a respective one of the first electrode units 31, respectively. Therefore, the first electrodes 311 of each of the first electrode units 31 have the same potential when activated.

The substrate 2 further has a back surface 22 opposite to the pattern-forming surface 21. The capacitive touch panel further includes a conductive grounding layer 9 formed on the back surface 22 of the substrate 2 so as to shield EMI (electromagnetic interference) from an LCD.

The substrate 2 is made from a material selected from one of a transparent dielectric material (e.g., glass) and an opaque dielectric material. Each of the patterned conductive layer 3 and the grounding layer 9 is formed of at least one film of a material selected from one of a transparent conductive material (e.g., ITO, IZO, or AZO) and a metallic material (e.g., Ag), and preferably has a trilayer structure (e.g., ITO/Ag/ITO).

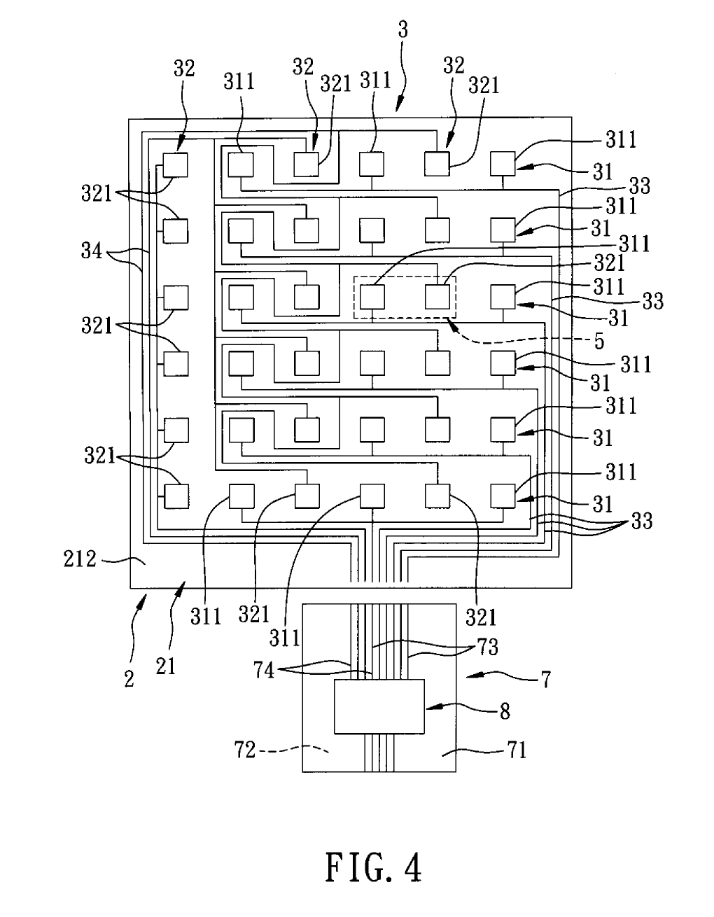

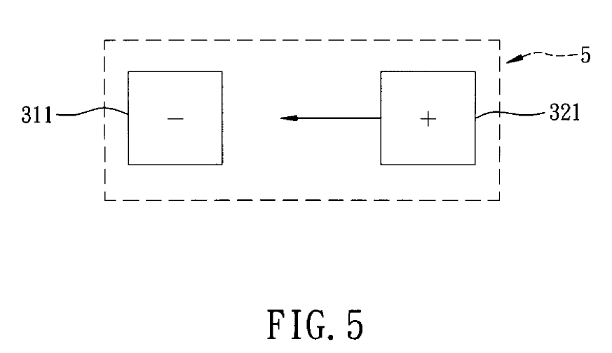

FIGS. 4 and 5 illustrate the second preferred embodiment of a capacitive touch panel according to this invention. The second preferred embodiment differs from the first preferred embodiment in structures of the patterned conductive layer 3 and the connector 7.

In this embodiment, the patterned conductive layer 3 does not include the interconnecting lines 35 of the first preferred embodiment, and the connector 7 does not include the via units 75 and the linking lines 76 of the first preferred embodiment.

Each of the first electrodes 311 of each of the first electrode units 31 is disposed between and aligned with two adjacent ones of the second electrodes 321 of two respective ones of the second electrode units 32. Each of the capacitive sensing units 5 includes one of the first electrodes 311 and a respective one of the second electrodes 321 adjacent thereto. An electric field generated by each of the capacitive sensing units 5 is represented by an arrow in FIG. 5.

Each of the first conductive lines 33 is connected to the first electrodes 311 of a respective one of the first electrode units 31, such that the first electrodes 311 of each of the first electrode units 31 have the same potential when activated.

Each of the second conductive lines 34 is connected to the second electrodes 321 of a respective one of the second electrode units 32, such that the second electrodes 321 of each of the second electrode units 32 have the same potential when activated.

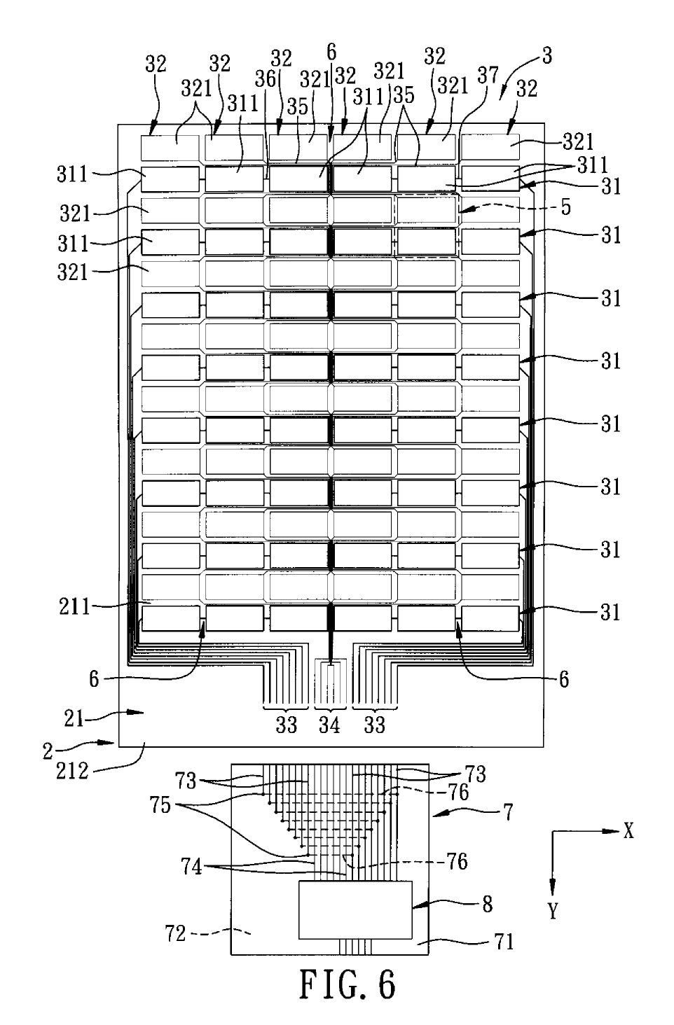

FIG. 6 illustrates the third preferred embodiment of a capacitive touch panel according to this invention. The third preferred embodiment differs from the first preferred embodiment in the structure of the patterned conductive layer 3.

In this embodiment, each of the first electrodes 311 of each of the first electrode units 31 is disposed between and aligned with two adjacent ones of the second electrodes 321 of a respective one of the second electrode units 32. Each of the capacitive sensing units 5 includes one of the first electrodes 311 and a respective one of the second electrodes 321 adjacent thereto.

The first electrodes 311 and the second electrodes 312 cooperatively define a plurality of channels 6, each of which extends in the first direction (Y) from the top side of the electrode-forming region 211 to the bottom side of the electrode-forming region 211. Each of the interconnecting lines 35 interconnects two adjacent ones of the second electrodes 321 of a respective one of the second electrode units 32, and extends into a central one of the channels 6.

The first conductive lines 33 are disposed at the outside of the electrode-forming region 211, and extend from the respective ones of the first electrodes 311 that are disposed adjacent to two opposite sides of the peripheral region 212 opposite to each other in the second direction (X).

The patterned conductive layer 3 further includes a plurality of conductive first connecting lines 36, each of which interconnects two adjacent ones of the first electrodes 311 of a respective one of the first electrode units 31 that are disposed at a left side (also referred to as one side herein) of the central one of the channels 6, and a plurality of conductive second connecting lines 37, each of which interconnects two adjacent ones of the first electrodes 311 of a respective one of the first electrode units 31 that are disposed at a right side (also referred to as the other side herein) of the central one of the channels 6.

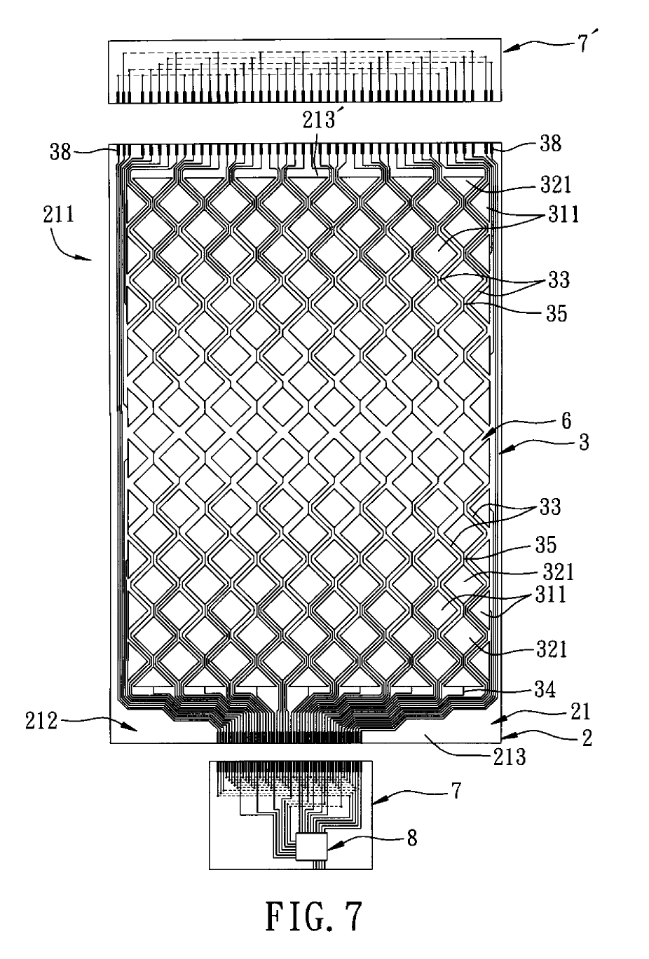

FIG. 7 illustrates the fourth preferred embodiment of a capacitive touch panel according to this invention. The fourth preferred embodiment differs from the first preferred embodiment in the following ways: a) the capacitive touch panel further includes another connector 7′, b) the peripheral region 212 of the pattern-forming surface 21 of the substrate 2 further has another bonding area 213′ adjacent to the top side of the electrode-forming region 211 and bonded to the connector 7′, and c) the patterned conductive layer 3 further includes a plurality of third conductive lines 38.

In this embodiment, the first conductive lines 33 disposed at a lower half of the pattern-forming surface 21 converge at the bonding area 213 to connect electrically to the controller 8 through the connector 7. The first conductive lines 33 disposed at an upper half of the pattern-forming surface 21 converge at the bonding area 213′ to connect electrically to the controller 8 through the connector 7′, the third conductive lines 38 of the patterned conductive layer 3, and the connector 7.

The fourth preferred embodiment is preferable when the capacitive touch panel is large in size and includes a large number of the first conductive lines 33.

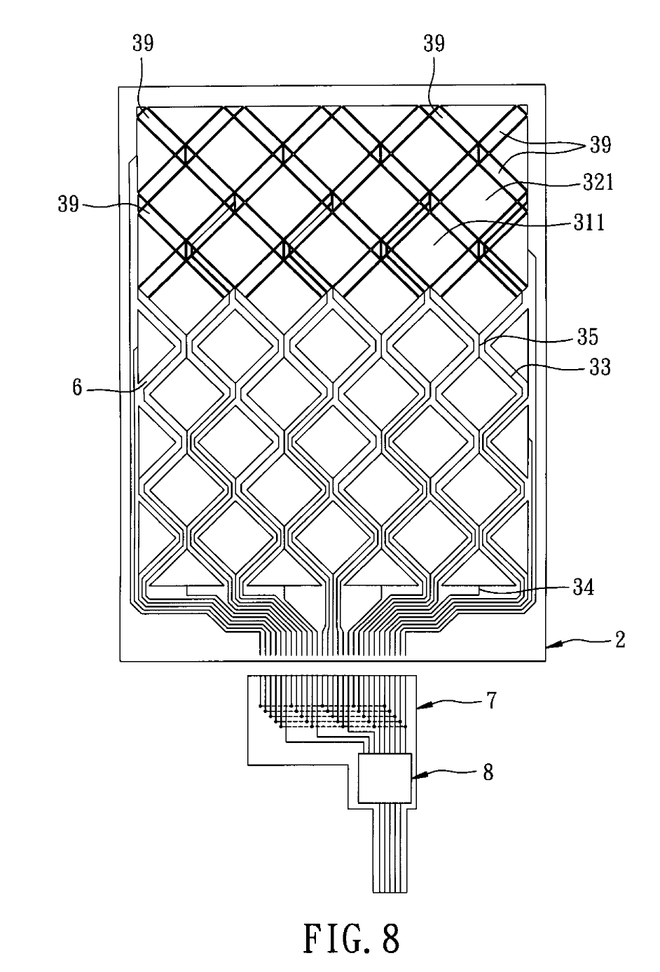

FIG. 8 illustrates the fifth preferred embodiment of a capacitive touch panel according to this invention. The fifth preferred embodiment differs from the first preferred embodiment in that the patterned conductive layer 3 further includes a plurality of dummy electrodes 39 disposed in the channels 6 defined by the second electrodes 321 of the second electrode units 32.

In this embodiment, the dummy electrodes 39 may be connected to a ground (not shown), may be connected to reference electrodes or floating electrodes (not shown), or may have no electrical connection with any other component. The dummy electrodes 39 can reduce the difference of light transmittance among the first electrodes 311, the second electrodes 321, and the channels 6 so as to simplify the design of an anti-reflection layer (not shown) formed on the patterned conductive layer 3. It is noted that the previous embodiments can also include the dummy electrodes 39 on the pattern-forming surface 21.

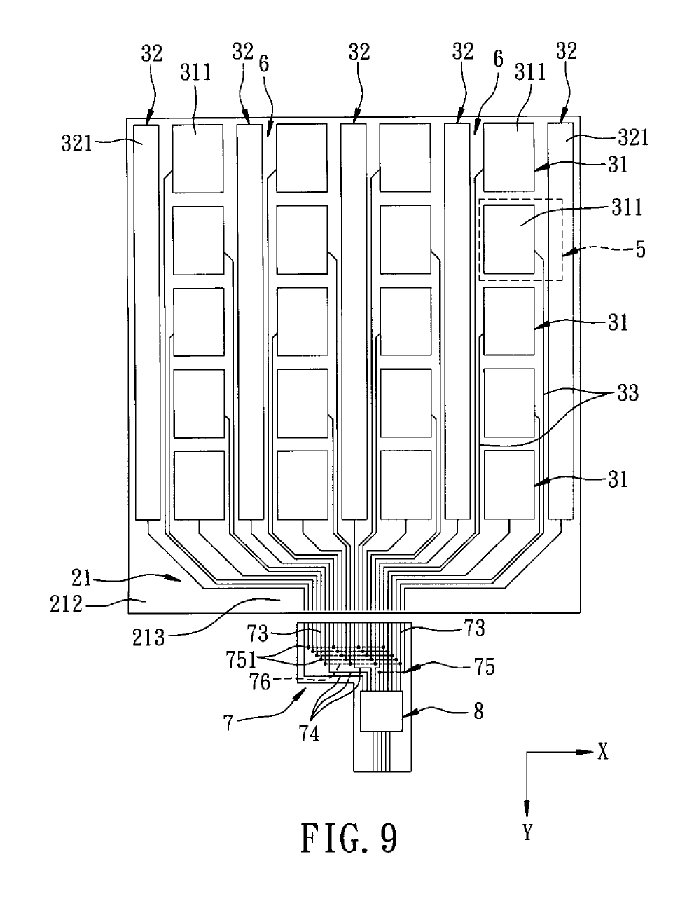

FIG. 9 illustrates the sixth preferred embodiment of a capacitive touch panel according to this invention. The sixth preferred embodiment differs from the first preferred embodiment in the structure of the patterned conductive layer 3.

In this embodiment, the patterned conductive layer 3 does not include the interconnecting lines 35. Each of the second electrode units 32 includes solely one second electrode 321 having an elongate bar shape. Each of the first electrodes 311 of each of the first electrode units 31 is rectangular in shape. It is noted that the sizes of the first electrodes 311 of each of the first electrode units 31 can be different, and can be gradually decreased along the first direction (Y) from the top side of the electrode-forming region 211 to the bottom side of the electrode-forming region 211. Each of the capacitive sensing units 5 includes a respective one of the first electrodes 311 and a portion of a respective one of the second electrodes 321 adjacent thereto.

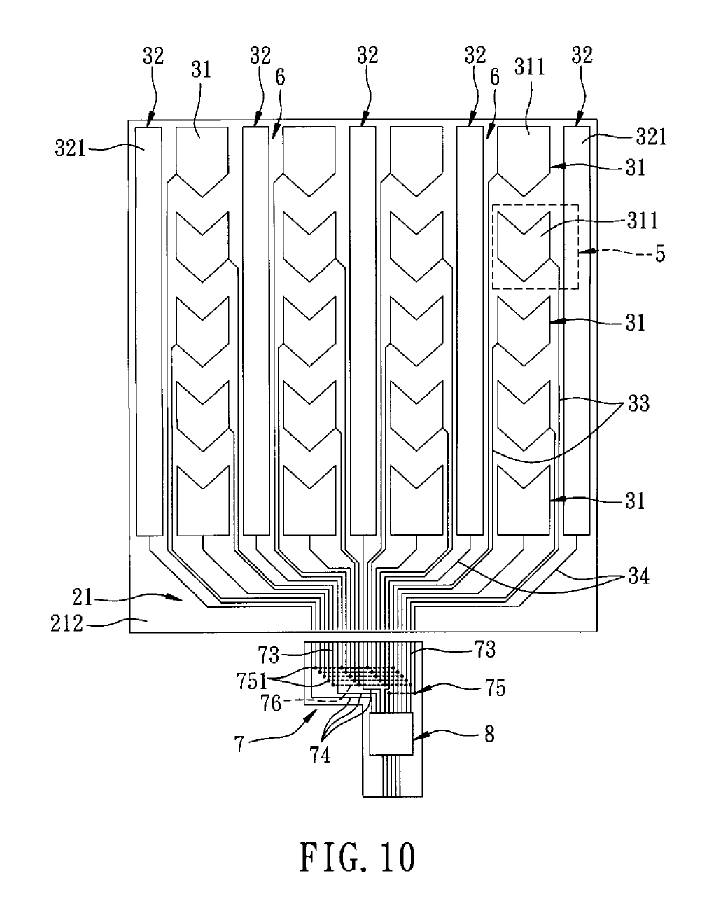

FIG. 10 illustrates the seventh preferred embodiment of a capacitive touch panel according to this invention. The seventh preferred embodiment differs from the sixth preferred embodiment in that the first electrodes 311 of the first electrode units 31 have an arrow (or concave polygonal) shape.

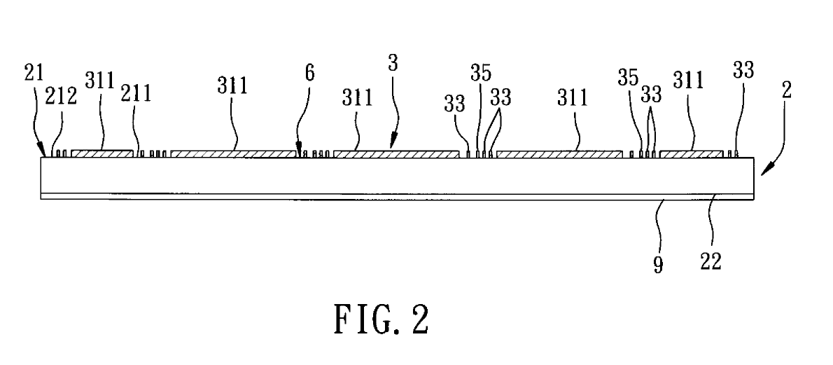

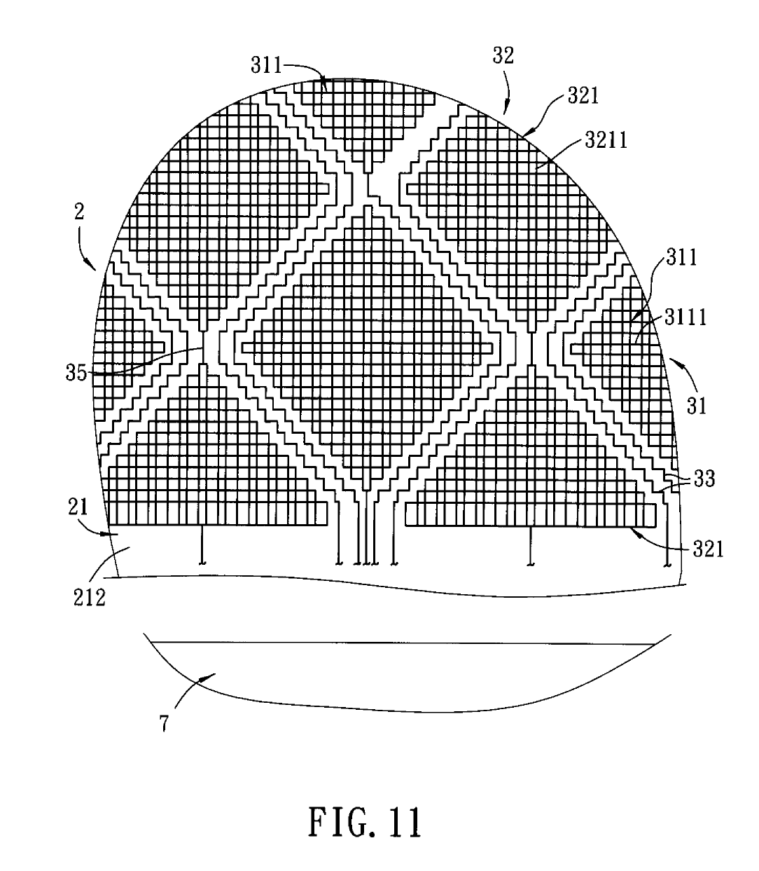

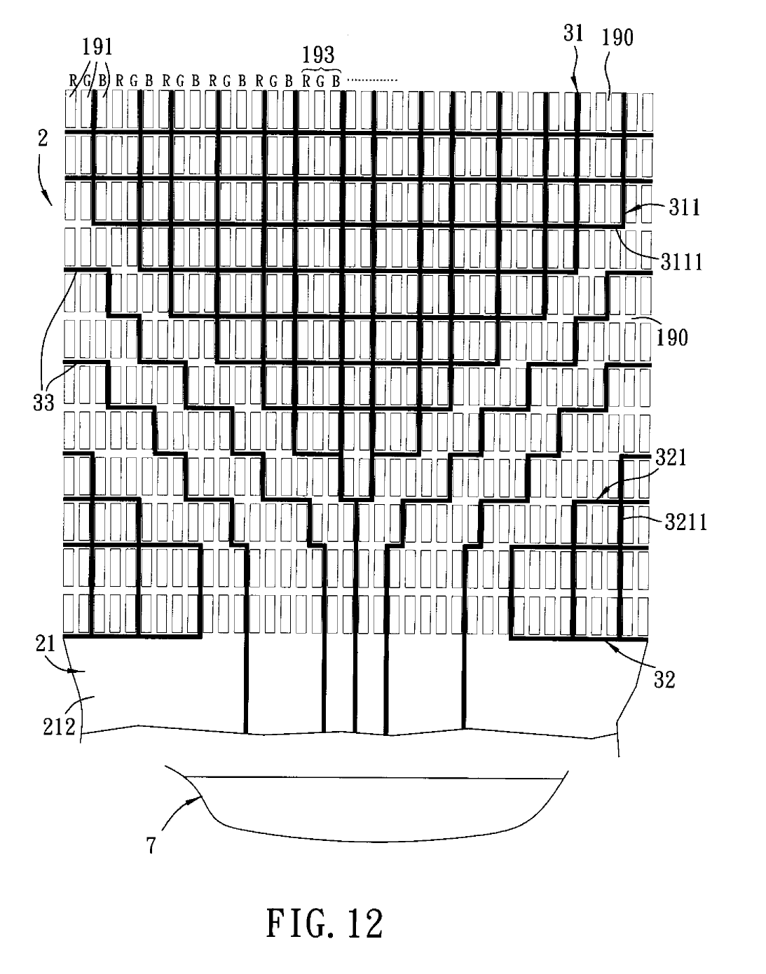

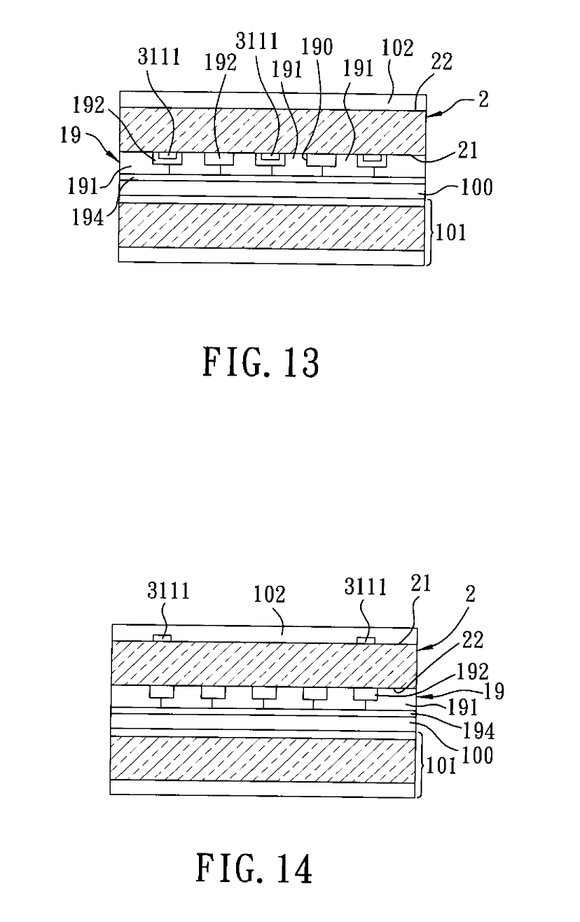

FIGS. 11 to 13 illustrate the eighth preferred embodiment of a capacitive touch panel according to this invention. The eighth preferred embodiment differs from the first preferred embodiment in that a color pixel layer 19 and a TFT array panel 101 of a liquid crystal display (not shown) are integrated with the capacitive touch panel of the first preferred embodiment to form an in-cell capacitive touch panel. In other embodiments, the capacitive touch panel of this invention can be integrated with a color pixel layer of an organic light-emitting diode (OLED) display, or of a plasma display panel (PDP), etc. The color pixel layer 19 is disposed on the substrate 2, and has an array of color pixels 193, each of which includes at least three sub-pixel color elements 191 that are different in color (e.g., Red, Green and Blue (BGR) color). The sub-pixel color elements 191 of the pixels 193 cooperatively define a network of grooves 190 thereamong. The color pixel layer 19 further has a black matrix 192 filling the grooves 190. Each of the first electrodes 311 is formed of a plurality of first conductive traces 3111. Each of the second electrodes 321 is formed of a plurality of second conductive traces 3211. Each of the first and second conductive traces 3111, 3211 is aligned with a segment of a respective one of the grooves 190 in a normal direction relative to the substrate 2. The first conductive traces 3111 of each of the first electrodes 311 cooperatively define a plurality of closed loops, each of which surrounds at least one of the sub-pixel color elements 191. The second conductive traces 3211 of each of the second electrodes 321 cooperatively defining a plurality of closed loops, each of which surrounds at least one of the sub-pixel color elements 191. The first and second conductive traces 3111, 3211 of each of the first and second electrodes 311, 321 are preferably made from metal or ITO. In this embodiment, the color pixel layer 19 is formed on the pattern-forming surface 21 of the substrate 2, and each of the first and second conductive traces 3111, 3211 is covered by the black matrix 192 (only the first conductive traces 3111 of one of the first electrodes 311 covered by the black matrix 192 are shown in FIG. 13 for the sake of brevity). An ITO layer 194 made from Indium Tin Oxide covers the sub-pixel color elements 191. It is noted that the grounding layer 9 (with reference to FIG. 2) of the first preferred embodiment is replaced with a polarizer film 102 in this embodiment. A liquid crystal material 100 is disposed between the ITO layer 194 and the TFT array panel 101. The ITO layer 194 serves as a common electrode for transistors and capacitors (not shown) on the TFT array panel 101 and as an EMI shielding layer for the capacitive touch panel.

FIG. 14 illustrates the ninth preferred embodiment of a capacitive touch panel according to this invention. The ninth preferred embodiment differs from the eighth preferred embodiment in that the color pixel layer 19 is formed on the back surface 22 of the substrate 2 and that the polarizer film 102 covers the first and second conductive traces 3111, 3211 (only the first conductive traces 3111 covered by the polarizer 102 are shown for the sake for brevity).

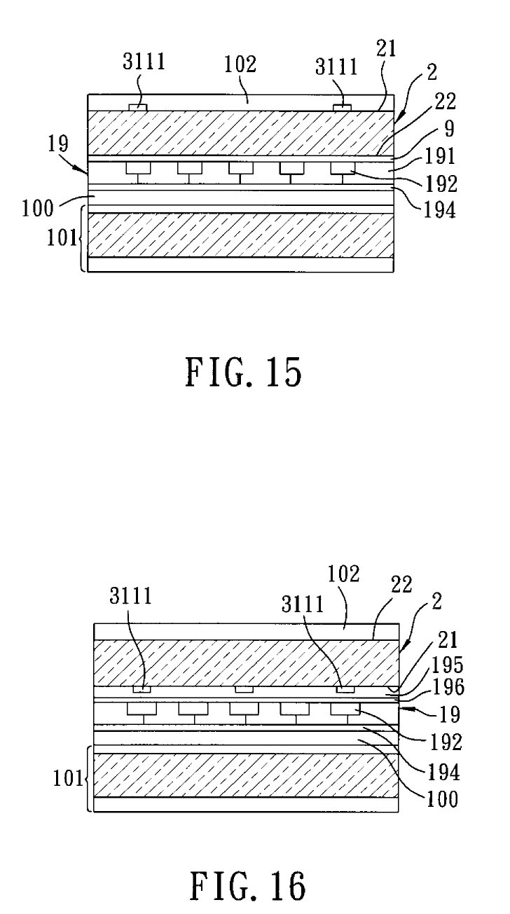

FIG. 15 illustrates the tenth preferred embodiment of a capacitive touch panel according to this invention. The tenth preferred embodiment differs from the ninth preferred embodiment in that a second ITO layer serving as the grounding layer 9 (see also FIG. 2) is formed on the back surface 22 of the substrate 2 and that the color pixel layer 19 is formed on and disposed between the first and second ITO layers 194, 9.

FIG. 16 illustrates the eleventh preferred embodiment of a capacitive touch panel according to this invention. The eleventh preferred embodiment differs from the eighth preferred embodiment in that the capacitive touch panel further includes an insulator layer 195 and a second ITO layer 196. The insulator layer 195 is formed on the pattern-forming surface 21 of the substrate 2 and covers the first and second conductive traces 3111, 3211 (only the first conductive traces 3111 covered by the insulator layer 195 are shown). The second ITO layer 196 is formed on the insulator layer 195. The color pixel layer 19 is formed on and disposed between the first and second ITO layers 194, 196.

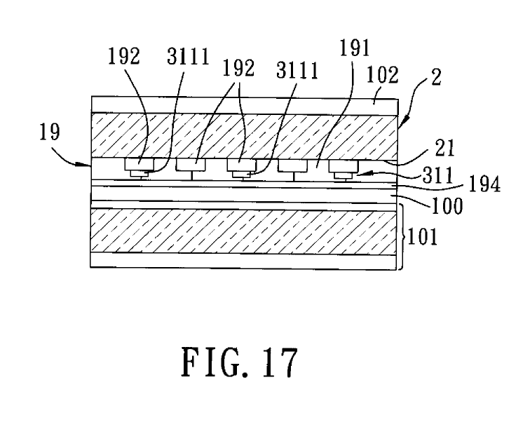

FIG. 17 illustrates the twelfth preferred embodiment of a capacitive touch panel according to this invention. The twelfth preferred embodiment differs from the eighth preferred embodiment in that the color pixel layer 19 is formed on the pattern-forming surface 21 of the substrate 2 and that the first and second electrodes 311, 321 are formed on the black matrix 192 so as to form the sensing units 5 (see FIG. 3) on the black matrix 192. It is noted that only the first conductive traces 3111 of the first electrodes 311 formed on the black matrix 192 are shown in FIG. 17 for the sake of brevity. In this embodiment, the black matrix 192 and the first and second conductive traces 3111, 3211 (only the first conductive traces 3111 are shown in FIG. 17) are embedded in the sub-pixel color elements 191. In previous embodiments, when the first and second conductive traces 3111, 3211 are made from ITO, the electrical resistance thereof would increase considerably with an increase in the size of the capacitive touch panel, thereby limiting the size of the capacitive touch panel, and when they are made from metal, such as silver or copper, to reduce the electrical resistance, undesired reflection caused by the first and second conductive traces 3111, 3211 can be observed by the user, thereby resulting in a poor display quality. In this preferred embodiment, the first and second conductive traces 3111, 3211 are hidden behind the black matrix 192, thereby permitting the use of metal as the material for the first and second conductive traces 3111, 3211. Hence, a large scale capacitive touch panel with excellent display quality can be realized by this preferred embodiment.

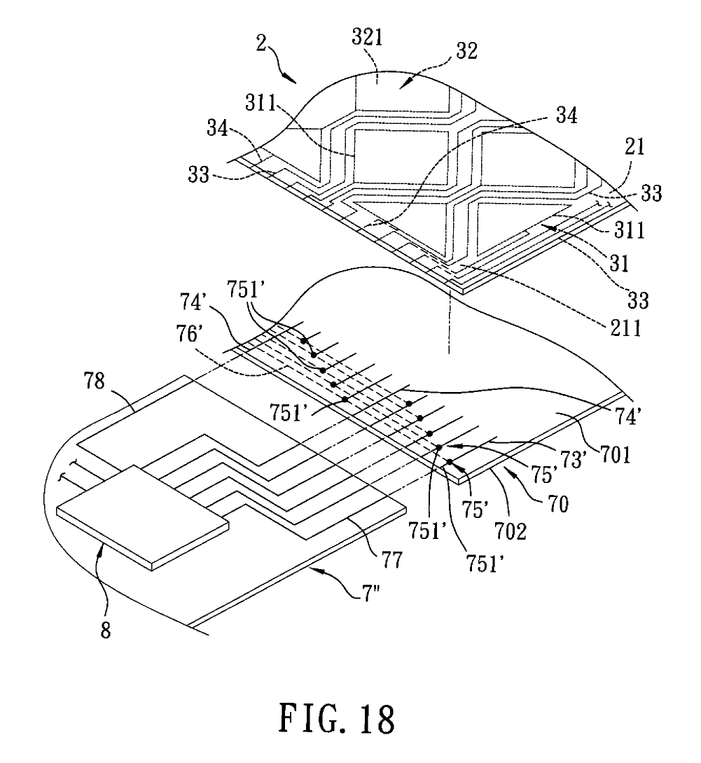

FIG. 18 illustrates the thirteenth preferred embodiment of a capacitive touch panel according to this invention. The thirteenth preferred embodiment differs from the first embodiment in that the first and second fingers 73′, 74′, the linking lines 76′ and the via units 75′ are formed on or in a second substrate 70. The second substrate 70 is made from glass, is spaced apart and overlaps the first substrate 2, and has opposite first and second surfaces 701, 702. The first surface 701 is formed with the first and second conductive fingers 73′, 74′. The first and second fingers 73′, 74′ are adhesively bonded to the first and second conductive lines 33, 34, respectively, through silver paste or anisotropic conductive paste (not shown). The second surface 702 is formed with the conductive linking lines 76′. Each of the vias 751′ of each of the via units 75′ extends through the first and second surfaces 701, 702 and is connected to a respective one of the first conductive lines 33. The vias 751′ of each of the via units 75′ are connected to a respective one of the linking lines 76′. In this embodiment, the IC controller 8 is bonded to a flexible printed circuit board 7″. The flexible printed circuit board 7″ has a plurality of first and second conductive traces 77, 78 connected to the IC controller 8 and bonded to the first and second fingers 73′, 74′, respectively.

By utilizing a configuration by which the first conductive lines 33 and the second conductive lines 34 do not cross each other, the patterned conductive layer 3 of the capacitive touch panel of this invention has a simple structure, and can be directly formed on the substrate 2 using a single photolithographic or other patterning step, which results in a simple manufacturing process and low manufacturing costs.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A capacitive touch panel comprising:
a substrate having a pattern-forming surface that is divided into an electrode-forming region and a peripheral region surrounding said electrode-forming region and having a bonding area;
a color pixel layer disposed on said substrate and having an array of color pixels, each of which includes at least three sub-pixel color elements that are different in color;
a patterned conductive layer formed on said pattern-forming surface and including a plurality of first electrode units formed on said electrode-forming region and aligned in a first direction, a plurality of second electrode units formed on said electrode-forming region and aligned in a second direction transverse to the first direction, a plurality of spaced apart first conductive lines, and a plurality of spaced apart second conductive lines, said first electrode units being capacitively coupled to said second electrode units so as to form a plurality of two dimensionally arranged capacitive sensing units in said electrode-forming region, each of said first electrode units including a plurality of first electrodes that are aligned in the second direction;
wherein each of said first conductive lines is connected to and extends along said pattern-forming surface from at least one of said first electrodes of a respective one of said first electrode units into said peripheral region, and said first conductive lines converge at said bonding area for electrically bonding to an external connector; and
wherein said second conductive lines extend along said pattern-forming surface from said second electrode units into said peripheral region, respectively, converge at said bonding area for electrically bonding to the external connector, and do not cross said first conductive lines.

2. The capacitive touch panel of claim 1, wherein each of said second electrode units includes a second electrode, said second electrodes of two adjacent ones of said second electrode units cooperatively defining a channel therebetween, said channel extending in the first direction from one side of said electrode-forming region to an opposite side of said electrode-forming region, said first electrodes of each of said first electrode units being disposed respectively in said channels defined by said second electrodes of said second electrode units.

3. The capacitive touch panel of claim 2, wherein some of said first conductive lines, each extending from the respective one of said first electrodes that is disposed at said opposite side of said electrode-forming region adjacent to said bonding area, are disposed outside of said electrode-forming region, while each of the remainder of said first conductive lines extends from the respective one of said first electrodes into and through said channel in which the respective one of said first electrodes is disposed.

4. The capacitive touch panel of claim 1, wherein each of said second electrode units includes a plurality of second electrodes that are aligned in the first direction, said patterned conductive layer further including a plurality of conductive interconnecting lines, each of which interconnects two adjacent ones of said second electrodes of a respective one of said second electrode units.

5. The capacitive touch panel of claim 4, wherein said second electrodes of two adjacent ones of said second electrode units cooperatively define a channel therebetween, said channel extending in the first direction from one side of said electrode-forming region to an opposite side of said electrode-forming region, said first electrodes of each of said first electrode units being disposed respectively in said channels defined by said second electrodes of said second electrode units.

6. The capacitive touch panel of claim 5, wherein some of said first conductive lines, each extending from the respective one of said first electrodes that is disposed at said opposite side of said electrode-forming region adjacent to said bonding area, are disposed outside of said electrode-forming region, while each of the remainder of said first conductive lines extends from the respective one of said first electrodes into and through said channel in which the respective one of said first electrodes is disposed.

7. The capacitive touch panel of claim 1, wherein each of said second electrode units includes a plurality of second electrodes that are aligned in the first direction, each of said first electrodes of each of said first electrode units being disposed between and aligned with two adjacent ones of said second electrodes of a respective one of said second electrode units.

8. The capacitive touch panel of claim 7, wherein said first and second electrodes cooperatively define a plurality of channels, each of which extends in the first direction from one side of said electrode-forming region to an opposite side of said electrode-forming region, said patterned conductive layer further including a plurality of conductive interconnecting lines, each of which interconnects two adjacent ones of said second electrodes of a respective one of said second electrode units and each of which extends into one of said channels.

9. The capacitive touch panel of claim 8, wherein said first conductive lines are disposed at the outside of said electrode-forming region and extend from the respective ones of said first electrodes that are disposed adjacent to two opposite sides of said peripheral region opposite to each other in the second direction, said patterned conductive layer further including a plurality of conductive first connecting lines, each of which interconnects two adjacent ones of said first electrodes of a respective one of said first electrode units that are disposed at one side of said one of said channels, and a plurality of conductive second connecting lines, each of which interconnects two adjacent ones of said first electrodes of a respective one of said first electrode units that are disposed at the other side of said one of said channels.

10. The capacitive touch panel of claim 1, wherein each of said second electrode units includes a plurality of second electrodes that are aligned in the first direction, each of said first electrodes of each of said first electrode units being disposed between and aligned with two adjacent ones of said second electrodes of two respective ones of said second electrode units, each of said first conductive lines being connected to said first electrodes of a respective one of said first electrode units, each of said second conductive lines being connected to said second electrodes of a respective one of said second electrode units.

11. The capacitive touch panel of claim 1, wherein said substrate further has a back surface opposite to said pattern-forming surface, said capacitive touch panel further comprising a conductive grounding layer formed on said back surface of said substrate.

12. The capacitive touch panel of claim 1, wherein said sub-pixel color elements of said pixels cooperatively define a network of grooves thereamong, said color pixel layer further having a black matrix filling said grooves.

13. The capacitive touch panel of claim 12, wherein each of said first electrodes is formed of a plurality of first conductive traces, each of said second electrode units including a plurality of second electrodes that are aligned in the first direction, each of said second electrodes being formed of a plurality of second conductive traces, each of said first and second conductive traces being aligned with a segment of a respective one of said grooves in a normal direction relative to said substrate.

14. The capacitive touch panel of claim 13, wherein said first conductive traces of each of said first electrodes cooperatively define a plurality of closed loops, each of which surrounds at least one of said sub-pixel color elements, said second conductive traces of each of said second electrodes cooperatively defining a plurality of closed loops, each of which surrounds at least one of said sub-pixel color elements.

15. The capacitive touch panel of claim 13, wherein said color pixel layer is formed on said pattern-forming surface of said substrate, each of said first and second conductive traces being covered by said black matrix.

16. The capacitive touch panel of claim 15, further comprising an ITO layer made from Indium Tin Oxide and covering said sub-pixel color elements.

17. The capacitive touch panel of claim 13, wherein said substrate further has a back surface opposite to said pattern-forming surface, said color pixel layer being formed on said back surface of said substrate.

18. The capacitive touch panel of claim 17, further comprising an ITO layer made from Indium Tin Oxide and covering said sub-pixel color elements.

19. The capacitive touch panel of claim 13, further comprising first and second ITO layers made from Indium Tin Oxide, said substrate further having a back surface opposite to said pattern-forming surface, said second ITO layer being formed on said back surface of said substrate, said color pixel layer being formed on and disposed between said first and second ITO layers.

20. The capacitive touch panel of claim 13, further comprising first and second ITO layers made from Indium Tin Oxide and an insulator layer, said insulator layer being formed on said pattern-forming surface of said substrate and covering said first and second conductive traces, said second ITO layer being formed on said insulator layer, said color pixel layer being formed on and disposed between said first and second ITO layers.

21. A capacitive touch panel adapted to be connected to a controller, comprising:
a substrate having a pattern-forming surface that is divided into an electrode-forming region and a peripheral region surrounding said electrode-forming region and having a bonding area;
a color pixel layer disposed on said substrate and having an array of color pixels, each of which includes at least three sub-pixel color elements that are different in color;
a patterned conductive layer formed on said pattern-forming surface and including a plurality of first electrode units formed on said electrode-forming region, a plurality of second electrode units formed on said electrode-forming region, a plurality of spaced apart first conductive lines, and a plurality of spaced apart second conductive lines, said first electrode units being capacitively coupled to said second electrode units so as to form a plurality of two dimensionally arranged capacitive sensing units in said electrode-forming region, each of said first electrode units including a plurality of first electrodes; and
a connector bonded to said bonding area of said peripheral region of said pattern-forming surface of said substrate for connecting electrically said first and second electrode units to the controller, said connector having a plurality of spaced apart first conductive fingers and a plurality of spaced apart second conductive fingers;
wherein each of said first conductive lines is connected to and extends along said pattern-forming surface from at least one of said first electrodes of a respective one of said first electrode units into said peripheral region, and said first conductive lines converge at said bonding area to connect electrically with said first conductive fingers, respectively; and
wherein said second conductive lines extend along said pattern-forming surface from said second electrode units into said peripheral region, respectively, do not cross said first conductive lines, and converge at said bonding area to connect electrically with said second conductive fingers, respectively.

22. The capacitive touch panel of claim 21, wherein said first conductive lines are connected to and extend from said first electrodes of said first electrode units, respectively, said connector further having a bonding surface and a connecting surface opposite to said bonding surface, said first and second conductive fingers being formed on said bonding surface, said connector further having a plurality of via units extending through said bonding surface and said connecting surface, and a plurality of spaced apart conductive linking lines formed on said connecting surface, each of said via units having a plurality of vias connected electrically to a respective one of said linking lines, each of said vias of each of said via units being connected electrically to a respective one of said first conductive fingers, each of said first conductive fingers being bonded to a respective one of said first conductive lines, each of said second conductive lines being bonded to a respective one of said second conductive fingers.

23. The capacitive touch panel of claim 22, wherein each of said second electrode units includes a second electrode, said second electrodes of two adjacent ones of said second electrode units cooperatively defining a channel therebetween, said channel extending from one side of said electrode-forming region to an opposite side of said electrode-forming region, said first electrodes of each of said first electrode units being disposed respectively in said channels defined by said second electrodes of said second electrode units.

24. The capacitive touch panel of claim 22, wherein some of said first conductive lines, each extending from the respective one of said first electrodes that is disposed at said opposite side of said electrode-forming region adjacent to said bonding area, are disposed outside of said electrode-forming region, while each of the remainder of said first conductive lines extends from the respective one of said first electrodes into and through said channel in which the respective one of said first electrodes is disposed.

25. The capacitive touch panel of claim 21, wherein said substrate further has a back surface opposite to said pattern-forming surface, said capacitive touch panel further comprising a conductive grounding layer formed on said back surface of said substrate.

26. The capacitive touch panel of claim 21, wherein said sub-pixel color elements of said pixels cooperatively define a network of grooves thereamong, said color pixel layer further having a black matrix filling said grooves.

27. The capacitive touch panel of claim 26, wherein each of said first electrodes is formed of a plurality of first conductive traces, each of said second electrode units including a plurality of second electrodes that are aligned in the first direction, each of said second electrodes being formed of a plurality of second conductive traces, each of said first and second conductive traces being aligned with a segment of a respective one of said grooves in a normal direction relative to said substrate.

28. The capacitive touch panel of claim 27, wherein said first conductive traces of each of said first electrodes cooperatively define a plurality of closed loops, each of which surrounds at least one of said sub-pixel color elements, said second conductive traces of each of said second electrodes cooperatively defining a plurality of closed loops, each of which surrounds at least one of said sub-pixel color elements.

29. A capacitive touch panel comprising:
a substrate;
a color pixel layer formed on said substrate and having an array of color pixels, each of which includes at least three sub-pixel color elements that are different in color, said sub-pixel color elements of said pixels cooperatively defining a network of grooves thereamong, said color pixel layer further having a black matrix filling said grooves; and
a patterned conductive layer including a plurality of first electrode units aligned in a first direction, and a plurality of second electrode units aligned in a second direction transverse to the first direction, each of said first electrode units including a plurality of first electrodes formed on said black matrix, each of said second electrode units including a plurality of second electrodes formed on said black matrix, said first electrode units being capacitively coupled to said second electrode units so as to form a plurality of two dimensionally arranged capacitive sensing units on the black matrix.

30. The capacitive touch panel of claim 29, wherein each of said first electrodes has a plurality of first conductive traces, each of said second electrodes having a plurality of second conductive traces, said black matrix and said first and second conductive traces being embedded in said sub-pixel color elements of said pixels, said capacitive touch panel further comprising an ITO layer of Indium Tin Oxide formed on said sub-pixel color elements of said pixels.

31. A capacitive touch panel comprising:
a first substrate having a pattern-forming surface that is divided into an electrode-forming region and a peripheral region surrounding said electrode-forming region and having a bonding area;
a patterned conductive layer formed on said pattern-forming surface and including a plurality of first electrode units formed on said electrode-forming region, a plurality of second electrode units formed on said electrode-forming region, a plurality of spaced apart first conductive lines, and a plurality of spaced apart second conductive lines, said first electrode units being capacitively coupled to said second electrode units so as to form a plurality of two dimensionally arranged capacitive sensing units in said electrode-forming region, each of said first electrode units including a plurality of first electrodes, each of said first conductive lines being connected to and extending along said pattern-forming surface from at least one of said first electrodes of a respective one of said first electrode units into said bonding area of said peripheral region, said second conductive lines extending along said pattern-forming surface from said second electrode units into said bonding area of said peripheral region, respectively, and not crossing said first conductive lines; and
a second substrate spaced apart and overlapping said first substrate and having opposite first and second surfaces, said first surface being formed with a plurality of spaced apart first conductive fingers and a plurality of spaced apart second conductive fingers, said first and second fingers being adhesively bonded to said first and second conductive lines, respectively, said second surface being formed with a plurality of conductive linking lines, said second substrate being formed with a plurality of via units, each of which includes a plurality of vias extending through said first and second surfaces and connected electrically to a respective one of said linking lines and a respective one of said first conductive lines.

32. The capacitive touch panel of claim 31, wherein said first and second substrates are made from glass.

33. The capacitive touch panel of claim 31, further comprising a flexible printed circuit board having a plurality of first and second conductive traces connected to said first and second fingers, respectively.
